(19) United States
(12) Patent Application Publication
(10) Pub. No.: US 2008/0023066 A1
(43) Pub. Date: Jan. 31, 2008

(54) TRANSPARENT ELECTRODES FORMED OF METAL ELECTRODE GRIDS AND NANOSTRUCTURE NETWORKS

(75) Inventors: David Hecht, Santa Monica, CA (US); George Gruner, Los Angeles, CA (US); Mark Topinka, Palo Alto, CA (US); Michael McGehee, Palo Alto, CA (US)

Correspondence Address: UNIDYM, 201 SOUTH LAKE AVE., SUITE 703, PASADENA, CA, 91101, US

(73) Assignees: UNIDYM, INC., Pasadena, CA (US); The Board of Trustees of the Leland Stanford Junior University, Palo Alto, CA (US)

(21) Appl. No.: 11/678,404

(22) Filed: Feb. 23, 2007

Related U.S. Application Data
(60) Provisional application No. 60/833,846, filed on Jul. 28, 2006.

(51) Int. Cl. H01L 31/00; B05D 5/12

(52) U.S. Cl. 136/256; 427/75; 977/762; 977/890

(57) ABSTRACT

An optoelectronic device comprising at least one nanostructure-film electrode is discussed. The optoelectronic device may further comprise a different material, such as a polymer, to fill pores in the nanostructure-film. Additionally or alternatively, the optoelectronic device may comprise an electrode grid superimposed on the nanostructure-film.

This application claims priority to U.S. Provisional Patent Application No. 60/833,846, filed Jul. 28, 2006, and entitled “TRANSPARENT ELECTRODES FORMED OF METAL ELECTRODE GRIDS AND NANOSTRUCTURE NETWORKS,” which is hereby incorporated herein by reference.

### COPYRIGHT & TRADEMARK NOTICE

A portion of the disclosure of this patent document contains material that is subject to copyright protection. The owner has no objection to the facsimile reproduction by any one of the patent document or the patent disclosure, as it appears in the Patent and Trademark Office patent file or records, but otherwise reserves all copyrights whatsoever.

Certain marks referenced herein may be common law or registered trademarks of third parties affiliated or unaffiliated with the applicant or the assignee. Use of these marks is by way of example and shall not be construed as descriptive or limit the scope of this invention to material associated only with such marks.

### FIELD OF THE INVENTION

The present invention relates in general to solar cells, and more particularly to thin-film solar cells comprising at least one nanostructure-film.

### BACKGROUND OF THE INVENTION

A solar cell is a photoelectric device that converts photons from the sun (solar light) into electricity. Fundamentally, the device needs to photo-generate charge carriers (e.g., electrons and holes) in a photosensitive active layer, and separate the charge carriers to conductive electrode(s) that will transmit the electricity.

Historically, bulk technologies employing crystalline silicon (c-Si) have been used as the light-absorbing semiconductors in most solar cells, despite the fact that c-Si is a poor absorber of light and requires a high material thickness (e.g., hundreds of microns). However, the high cost of c-Si wafers has led the industry to research alternate, and generally less-expensive, solar cell materials.

Specifically, thin film solar cells can be fabricated with relatively inexpensive materials on flexible surfaces. The selected materials are preferably strong light absorbers and need only be about a micron thick, thereby reducing materials costs significantly. Thin film solar cell materials include, but are not limited to, those based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes) and other non-silicon semiconductor materials. These materials are generally amenable to large area deposition on rigid (e.g., glass) or flexible (e.g., PET) substrates, with semiconductor junctions formed in different ways, such as a p-i-n device (e.g., with amorphous silicon) or a hetero-junction (e.g., with CdTe and CIS).

Regardless of the thin-film device architecture chosen, an at least semi-transparent conducting layer is generally required to form a front electrical contact of the cell, so as to allow light transmission through to the active layer(s). As used herein, a layer of material or a sequence of several layers of different materials is said to be “transparent” when the layer or layers permit at least 50% of the ambient electromagnetic radiation in relevant wavelengths to be transmitted through the layer or layers. Similarly, layers that permit some but less than 50% transmission of ambient electromagnetic radiation in relevant wavelengths are said to be “semi-transparent.”

Currently, the most commonly used transparent electrodes are transparent conducting oxides (TCOs), specifically indium-tin-oxide (ITO) on glass. However, ITO can be an inadequate solution for many emerging applications (e.g., non-rigid solar cells due to ITO's brittle nature), and the indium component of ITO is rapidly becoming a scarce commodity. Moreover, deposition of transparent conducting oxides (TCOs) for minimal light loss normally requires a high-temperature sputtering process, which can severely damage underlying active layers.

Consequently, more robust and abundant transparent conductors are required not only for solar cell applications but for optoelectronic applications in general.

### SUMMARY OF THE INVENTION

The present invention provides an optoelectronic device comprising at least one nanostructure-film.

Nanostructure-films include, but are not limited to, network(s) of nanotubes, nanowires, nanoparticles and/or graphene flakes. Specifically, transparent conducting nanostructure-films composed of randomly distributed single-wall nanotubes (SWNTs) (networks) have been demonstrated as substantially more mechanically robust than ITO. Additionally, SWNTs can be deposited using a variety of low-impact methods (e.g., they can be solution processed) and comprise carbon, which is one of the most abundant elements on Earth. Nanostructure-films according to embodiments of the present invention were demonstrated as having sheet resistances of less than 200 Ω/square with at least 85% optical transmission of 550 nm light.

A solar cell according to an embodiment of the present invention comprises a photosensitive active layer sandwiched between a first electrode and a second electrode, wherein at least one of the first and second electrodes comprises a network of nanostructures (e.g., a nanostructure-film). Active layers compatible with the present invention may include, but are not limited to, those based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes (e.g., PCBM)) and other non-silicon semiconductor materials. These materials are generally amenable to large area deposition on rigid (e.g., glass) or flexible (e.g., PET) substrates, with semiconductor junctions formed in different ways, such as a p-i-n device (e.g., with amorphous silicon) or a hetero-junction (e.g., with CdTe and CIS).

A solar cell according to a further embodiment of the present invention may additionally incorporate a different material (e.g., a polymer) that may serve to fill open porosity in the nanostructure (e.g., SWNT) network, encapsulate the network and/or planarize the network (thereby preventing shorting by wayward nanostructures through the active layer of the cell to another electrode). The different material may be mixed with nanostructures prior to deposition (e.g., to form a composite), and/or may be deposited separately (e.g., and allowed to diffuse into the nanostructure network).

The solar cell of the present invention may further comprise an electrode grid that is, for example, superimposed on the nanostructure network. This electrode grid may be composed of a conventional metal and/or may be at least semi-transparent (e.g., composed of nanostructures and/or ITO).

This and the above device architectures may be equally applicable to other optoelectronic devices. Other features and advantages of the invention will be apparent from the accompanying drawings and from the detailed description. One or more of the above-disclosed embodiments, in addition to certain alternatives, are provided in further detail below with reference to the attached figures. The invention is not limited to any particular embodiment disclosed.

### BRIEF DESCRIPTION OF THE DRAWINGS

The invention is better understood from reading the following detailed description of the preferred embodiments, with reference to the accompanying figures in which:

FIG. 1 is a schematic representation of an optoelectronic device according to an embodiment of the present invention;

FIG. 2 shows the sheet resistance versus optical transmission for nanostructure-films produced according to embodiments of the present invention;

FIG. 3 shows atomic force microscope (AFM) images of SWNT networks (a) before and (b) after PEDOT:PSS deposition and annealing;

FIG. 4 shows the current density-voltage characteristics of an organic solar cell according to an embodiment of the present invention under AM 1.5G conditions, as well as the current density-voltage characteristics for an organic solar cell with an ITO transparent electrode, for performance comparison;

FIG. 5 is a schematic representation of an optoelectronic device architecture according to an embodiment of the present invention, comprising a nanostructure-film, a electrode grid, and an active layer;

FIG. 6 is a schematic representation of an optoelectronic device architecture according to another embodiment of the present invention, comprising a conductive composite layer, an electrode grid, and an active layer;

FIG. 7 is a schematic representation of an optoelectronic device architecture according to yet another embodiment of the present invention, further comprising a conducting polymer layer;

FIG. 8 is a graph of the optical transmission of a PEDOT binder-carbon nanotube network for light of given wavelengths;

FIG. 9 illustrates several nanostructure deposition methods that are compatible with embodiments of the present invention; and

FIG. 10 is a flowchart outlining a nanostructure-film fabrication method according to embodiments of the present invention.

Features, elements, and aspects of the invention that are referenced by the same numerals in different figures represent the same, equivalent, or similar features, elements, or aspects in accordance with one or more embodiments of the system.

### DETAILED DESCRIPTION OF THE PREFERRED EMBODIMENTS

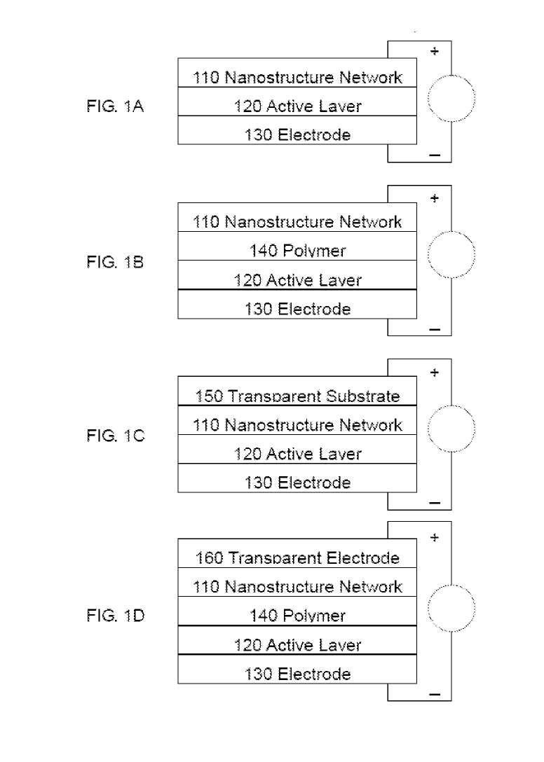

Referring to FIG. 1A, an optoelectronic device (e.g., solar cell) according to an embodiment of the present invention comprises a nanostructure-film 110, an active layer 120 and an electrode 130. A solar cell is an optoelectronic device that converts photons from the sun (solar light) into electricity—fundamentally, such a device needs to photo-generate charge carriers (e.g., electrons and holes) in an active layer, and separate the charge carriers to conductive electrodes that will transmit the electricity.

A solar cell active layer 120, according to embodiments of the present invention, is preferably a strong light absorber such as, for example, one based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes (e.g., PCBM) and other non-silicon semiconductor materials. These materials are generally amenable to large area deposition on rigid (e.g., glass) or flexible (e.g., PET) substrates, with semiconductor junctions formed in different ways, such as a p-i-n device (e.g., with amorphous silicon) or a hetero-junction (e.g., with CdTe and CIS).

The nanostructure-film 110 (also referred to herein as “nanostructure network”) preferably comprises an interconnected network of nanotubes, nanowires, nanoparticles and/or graphene flakes. This nanostructure-film 110 is preferably at least semi-transparent so as to allow light transmission through to the active layer(s), and electrically conductive so as to collect separated charges (e.g., electrons) from the underlying active layer (e.g., as an anode). As used herein, a layer of material or a sequence of several layers of different materials is said to be “transparent” when the layer or layers permit at least 50% of the ambient electromagnetic radiation in relevant wavelengths to be transmitted through the layer or layers. Similarly, layers which permit some but less than 50% transmission of ambient electromagnetic radiation in relevant wavelengths are said to be “semi-transparent.”

The electrode 130 (e.g., cathode) is also preferably electrically conductive so as to collect separated charges (e.g., electrons) from the active layer. This electrode 130 may also be at least semi-transparent, but needs not be in many devices (e.g., where another device electrode comprises a transparent and conductive nanostructure-film).

Referring to FIG. 1B, an optoelectronic device according to another embodiment of the present invention additionally comprises a polymer 140, for example, between the active layer 120 and nanostructure network 110. This polymer may be electrically conductive so as to increase collection of separated charges (e.g., by filling in open porosity in the nanostructure network 110). Additionally or alternatively, this polymer may comprise an encapsulation material (e.g., a fluoropolymer) and/or a buffer layer. Moreover, this layer can also serve to smooth the nanostructure layer so as to prevent the development of shorts through the active layer (e.g., where the active layer is relatively thin).

The polymer 140 may be deposited separately from the nanostructure-film, and/or may be mixed with the nanostructures and deposited as a composite layer. For example, SWNTs can be dispersed in aqueous solution and sonicated for a period of time, then mixed with an aqueous solution containing a polymer. The resulting mixture can then be sonicated and spin-coated onto a substrate, with the resulting film subsequently cured over a hotplate. Additionally or alternatively, a nanostructure network may be first deposited on a substrate, with a conducting polymer solution subsequently deposited onto the nanostructure network and allowed to freely diffuse.

In a preferred embodiment, the nanostructure network comprises substantially SWNTs, and the polymer comprises PEDOT:PSS (i.e., a conducting polymer). Other suitable conducting polymers may include, but are not limited to, ethylenedioxythiophene (EDOT), polyacetylene and poly(para phenylene vinylene) (PPV). Additional layers can be used to optimize parameters such as the work function of the layer (e.g., as a buffer layer). The composite layer may additionally contain conducting nanoparticles to be used as resins for increasing the viscosity of nanostructure solutions. As used herein, “substantially” shall mean that at least 40% of components are of a certain type.

In one experiment, a poly(3,4-ethylenedioxythiophene):poly(styrene sulfonate) (PEDOT:PSS) solution deposited onto a nanostructure network comprising single walled carbon nanotubes (SWNTs) reduced electrode sheet resistance by about 20% (e.g., to about 160 Ω/square). Given that the same PEDOT:PSS film (˜95 nm thick) spun on glass (i.e., with no nanostructures) had a sheet resistance of about 15 kΩ/square, the above drop in sheet resistance cannot be attributed merely to parallel conduction. Rather, the reduction in electrode sheet resistance may be attributed to a reduction in sheet resistance between conducting SWNTs (e.g., by filling a plurality of pores in the network) and/or doping of semiconducting SWNTs in the network.

Referring to FIGS. 1C and 1D, an optoelectronic device according to additional embodiments of the present invention may further comprise a transparent substrate 150. The substrate 150 may be rigid or flexible, and may comprise, for example, glass, polyethylene terephthalate (PET), polyethylene naphthalate (PEN), polycarbonate (PC), polyethersulfone (PES) and/or Arton.

Nanostructure network(s) 110 may be deposited on the substrate 150 through a variety of techniques such as, for example, spraying, drop-casting, dip-coating and transfer printing, which are discussed in greater detail below.

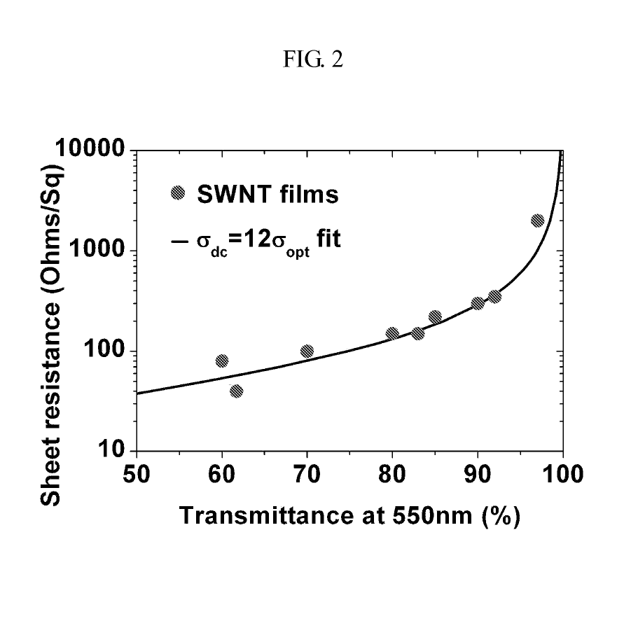

Referring to FIG. 2, a sheet resistance versus optical transmission graph is indicative of the optoelectronic performance of nanostructure-films produced according to embodiments of the present invention (e.g., wherein the nanostructures are SWNTs). As in most materials, thicker films have a lower sheet resistance (i.e., higher electrical conductivity) and optical transmittance (i.e., less light can pass through a thicker material) than thinner films. Nanostructure-film performance can be tailored to given device requirements by, for example, increasing or decreasing film thickness to attain desired transmittance and electrical conductivity.

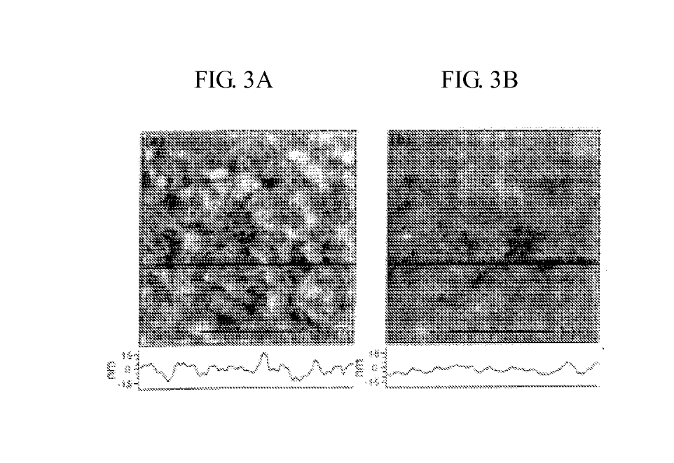

Referring to FIG. 3, atomic force microscope (AFM) images evidence nanostructure-films produced according to an embodiment of the present invention (a) before (see FIG. 3A) and (b) after (see FIG. 3B) PEDOT:PSS deposition and annealing. The nanostructure-films comprised SWNTs, and displayed substantial uniformity.

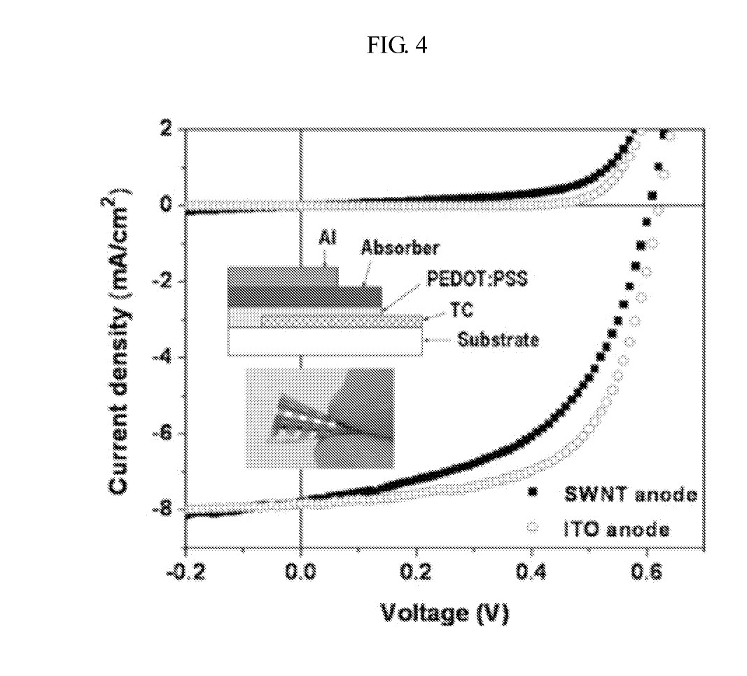

Referring to FIG. 4, a nanostructure-film electrode solar cell according to an embodiment of the present invention (e.g., using films similar to those imaged in FIG. 3) displayed performance comparable to conventional ITO electrode solar cells. In the tested embodiment, the organic active layer comprised P3HT:PCBM and the nanostructure-film electrode comprised a SWNT network(s) (e.g., on a flexible PET substrate) as an anode. Current density-voltage characteristics were plotted against another P3HT:PCBM device employing an ITO (e.g., on glass) anode. Under AM 1.5G conditions, the devices fabricated using SWNT networks performed comparably to those using ITO-coated glass.

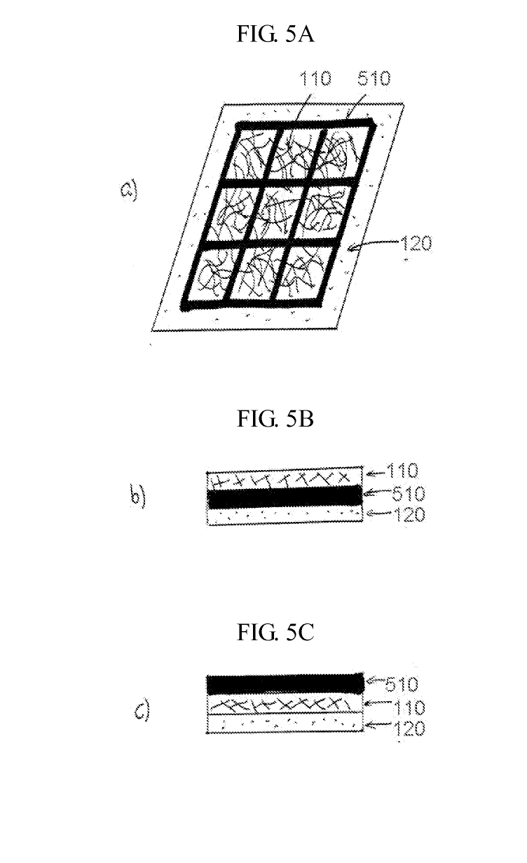

Referring to FIG. 5, a solar cell according to yet another embodiment of the present invention comprises an electrode grid 510 (e.g., bus bars), a nanostructure-film 110, and an active layer 120. Patterned metal electrode grids are used in various applications, ranging from solar cells to touch screens and displays. These grids display good electrical conductivities and can gather separated charges from underlying active layer(s), but only if those charges can reach points on the functional layer(s) that contact the grid(s). Unfortunately, such grids are generally not transparent and the electrodes thereof must typically be spaced relatively far apart to avoid unduly reducing light transmission to/from the underlying functional layer(s) (i.e., reduction is proportional to the fractional area covered by the metals). Consequently, devices (e.g., optoelectronics) in which charges are collected solely by a metal electrode grid(s) are usually quite inefficient, as many separated charges recombine before reaching an electrode.

A transparent conductor, such as a nanostructure-film 110, that fills gaps in the metal electrode grid can improve device efficiency significantly by allowing separated charges additional collection pathways. As depicted in FIGS. 5B and 5C, respectively, the nanostructure network 110 can be deposited on top of and/or below the electrode grid. Additionally or alternatively, as depicted in FIG. 5A, the nanostructure network 110 can be deposited between the electrodes (e.g., bus bars) of the electrode grid. The nanostructure network 110 will generally enhance device performance through its high work function, while the electrode grid 510 typically acts as the primary charge-harvesting element, to which charge and current flow from the nanostructure network 110. In other words, the nanostructure network is critical in that it provides a relatively low-resistance path to the electrode grid; however without the electrode grid, large resistive efficiency losses would occur—the electrode grid is advantageous in that it can be relatively thick (as little light is expected to penetrate through it to the active layer anyway) and consequently can have a very high electrical conductivity.

The electrode grid may comprise a conventional metal, for example gold. Metal electrode grids can be fabricated using known processes such as standard lithographic techniques, shadow masking, and gold deposition techniques. As used herein, “grid” shall mean a layer having openings (e.g. corrugated, perforated) penetrating through it, and shall include, for example, a framework of crisscrossed and/or parallel bars.

Additionally or alternatively, in a further embodiment of the present invention, the electrode grid is at least semi-transparent, comprising, for example, a patterned nanostructure network(s) (given that a thick nanostructure network can have metallic properties) and/or ITO. For example, such a device may comprise a thin SWNT network superimposed on a thick SWNT network, wherein the latter network acts as an electrode grid.

Various methods for fabricating and depositing nanostructure networks are described in PCT application US/2005/047315 entitled “Components and Devices Formed Using Nanoscale Materials and Methods of Production,” which is herein incorporated in its entirety by reference.

In an additional embodiment of the present invention, a nanostructure network solar cell fabricated according to the method described by M. Rowell, et al., Appl. Phys. Lett 88, 233506 (2006) can be improved by incorporating the electrode architecture of the present invention.

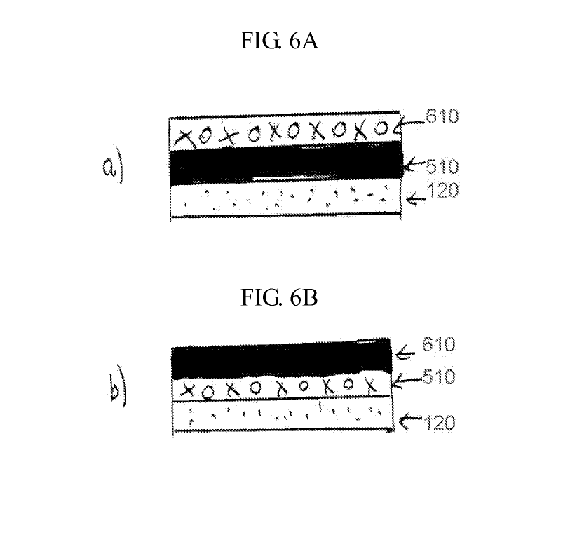

Referring to FIGS. 6A and 5B, a further embodiment of the present invention includes an architecture comprising an electrode grid 510 and a composite layer 610. The composite layer 610 may comprise a nanostructure network and at least one additional conducting material. For example, the composite layer 610 may be a SWNT network and a conducting polymer, wherein the conducting polymer serves as a binder for the nanostructure network. Such nanostructure networks have been shown to have very robust mechanical and electrical properties, as described above.

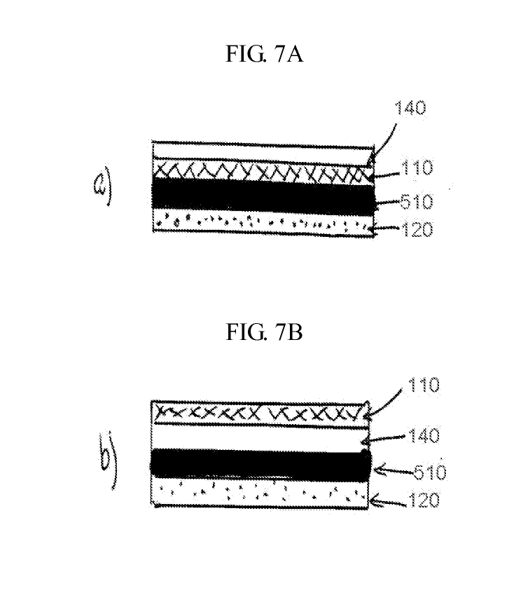

Referring to FIGS. 7A and 7B, the nanostructure network 110 and different material can also or alternatively form a multi-layer structure. The different material may be a conducting polymer (e.g., PEDOT:PSS) forming a distinct layer 140 on top of or beneath the nanostructure network 110, while preferably filling a plurality of pores in the nanostructure network 110. In the context of an optoelectronic device, this polymer may act as a buffer layer.

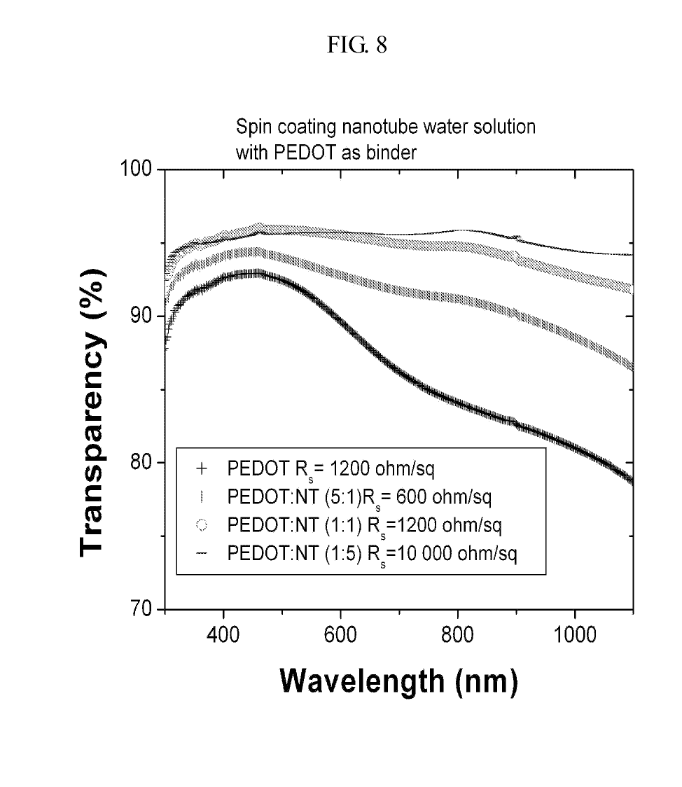

Referring to FIG. 8, an optical transmission graph of a PEDOT binder-SWNT network demonstrates the viability of the nanostructure networks of the present invention for optoelectronic applications.

To fabricate this exemplary sample, water soluable P3 arc-discharged nanotube powder from Carbon Solutions, Inc. was first dispersed in distilled oxide (DI) water by bath sonication with 100 W for 2 hours. Nanotube solution and PEDOT:PSS (Baytron F. HC) in water were then mixed together in different proportions, and the resulting mixture was subsequently bath-sonicated for 1 hour. The mixture was then spin-coated onto a pre-cleaned glass slide at a speed of 1000 rpm, and cured over a hotplate at 120 degrees for 18 minutes. The transmittance and sheet resistance of the deposited films was measured and plotted in FIG. 8.

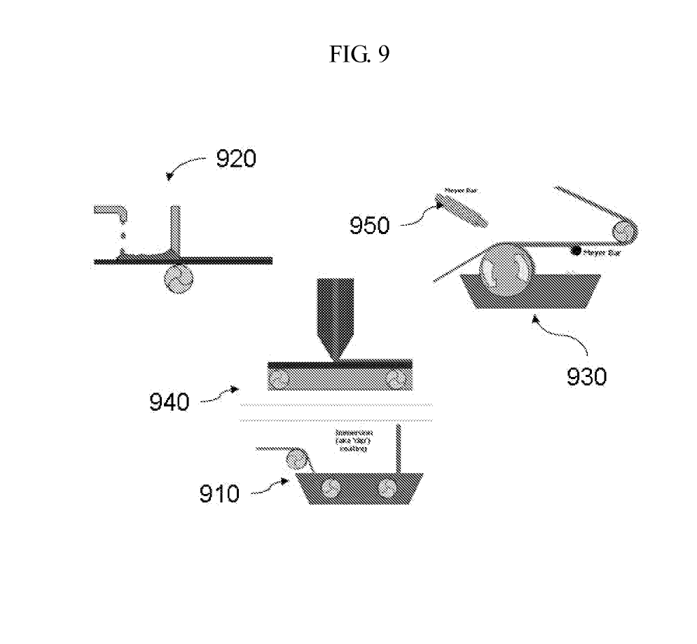

Referring to FIG. 9, in addition to spin-coating with a conductive polymer binder, a nanostructure solution/film may be deposited onto a substrate using a number of different methods. Such methods include, but are not limited to, spray coating, dip coating 910, drop coating 920 or casting, roll coating 930 and/or inkjet printing 940. A Meyer rod 950 may be used to squeeze the solutions for a more uniform nanostructure solution coating.

Additionally or alternatively, nanostructures may be deposited using a transfer stamping method. For example, commercially available SWNTs (e.g., produced by arc discharge) may be dissolved in solution with surfactants and then sonicated. The well dispersed and stable solutions may then be vacuum filtered over a porous alumina membrane. Following drying, the SWNT films may be lifted off with a poly(dimethylsiloxane) (PDMS) stamp and transferred to a flexible poly(ethylene terephthalate) (PET) substrate by printing.

This method has the added advantage of allowing deposition of patterned films (e.g., where the PDMS stamp is already patterned). Other compatible patterning methods include, but are not limited to, photolithography/etching and liftoff (e.g., using photoresist or toner).

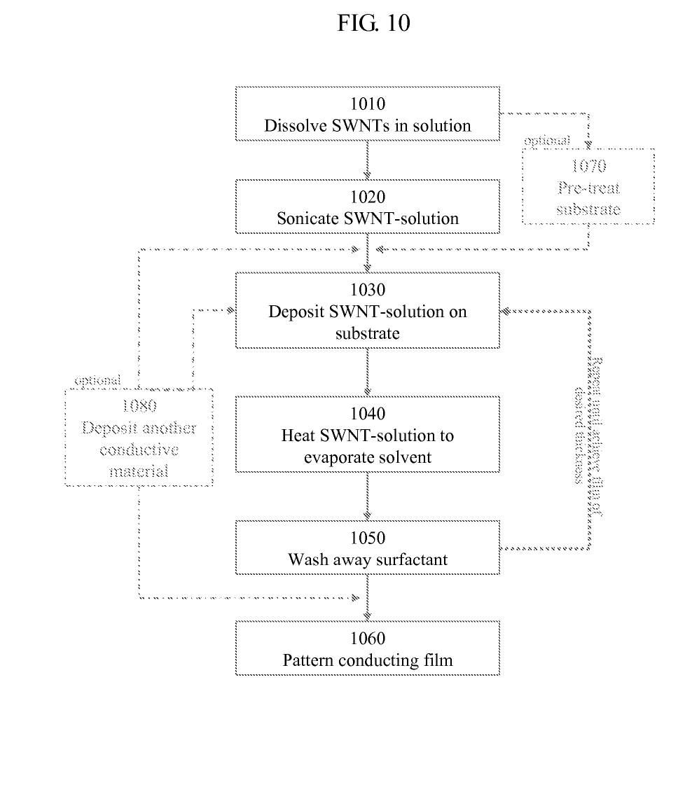

Referring to FIG. 10, a method for fabricating optoelectronic devices according to above-described and other embodiments of the present invention is provided. This method may comprise preparing a nanostructure solution (e.g., by dissolving SWNTs in solution 1010 and sonicating 1020) and pre-treating a substrate 1070. This latter step may be omitted depending on the types of substrates and surfactants used (e.g., transparent substrates such as PET, PEN, polycarbonate, or glass do not generally require pretreatment if Triton-X is used as a surfactant).

At this point, a polymer may be mixed with the nanostructure solution and deposited as a composite. Additionally or alternatively, the nanostructure solution may be deposited on the substrate 1030 by itself to form a nanostructure network, with a polymer already deposited 1080 on the substrate or subsequently deposited onto the nanostructure network and allowed to freely diffuse. Preferably, even where the polymer is deposited separately from the nanostructure network, it will fill a plurality of pores in the adjacent nanostructure network.

After deposition, solvent may be evaporated from the solution 1040 and/or composite, preferably in a uniform manner using, for example, a flash-drying method (where evaporation begins on one side of the substrate, and sweeps across the substrate in a “drying wave”). Heat can be applied in various manners, e.g., by linear heating bar and/or infrared laser. Additionally, solvent evaporation may be aided by air-flow blow drying.

Where a surfactant is used, the substrate will preferably undergo a subsequent wash to remove surfactant from the dried nanostructure-film on the substrate 1050. Washing may comprise rinsing the film with water and/or methanol, and then drying it with air-flow blow dry or heat.

The composite and/or nanostructure-film may be patterned before (e.g., using PDMS stamp transfer), during (e.g., using a lift-off technique) and/or after (e.g., using photolithography and etching) deposition.

In an exemplary embodiment, a nanostructure solution may be prepared by dispersing water soluble P3 arc-discharged nanotube powder from Carbon Solutions Inc. in DI water by bath sonication with 100 W for 2 hours. A PET substrate with an electrode grid (e.g., a metal electrode grid fabricated using known metal deposition and patterning techniques) formed thereon may be dipped into this solution, such that a 30-nm-thick SWNT network film (T=85%, Rs=200 Ω/square) is formed. This film may be subsequently coated with PEDOT:PSS by spin-casting (e.g., at 1000 rpm) and heating of the substrate (e.g., on a 110° C. hotplate for 20 minutes). Consistent results were obtained when either the PEDOT:PSS solution was applied on the surface and let free to diffuse several minutes before the spin-coating operation in order to fill in open porosity of the SWNT film or when a PEDOT:PSS/isopropanol 1:1 mix was used to improve the wetting.

An active layer may subsequently be deposited over the nanostructure network and/or polymer. Preferably, the active layer is photosensitive and may be based on silicon (e.g., amorphous, protocrystalline, nanocrystalline), cadmium telluride (CdTe), copper indium gallium selenide (CIGS), chalcogenide films of copper indium selenide (CIS), gallium arsenide (GaAs), light absorbing dyes, quantum dots, organic semiconductors (e.g., polymers and small-molecule compounds like polyphenylene vinylene, copper phthalocyanine and carbon fullerenes) and other non-silicon semiconductor materials.

In an exemplary embodiment, an organic active layer may be deposited by transferring the PET substrate coated with the 30-nm-thick SWNT film and a PEDOT:PSS layer with low roughness to an inert glove box where a solution of MDMO-PPV/PCBM in a 1:4 weight ratio or P3HT/PCBM in a 1:0:8 weight ratio (10 mg P3HT/mL) in chlorobenzene was spin-cast at 700 rpm.

In another exemplary embodiment, thin silicon active layers may be deposited over the SWNT film by chemical vapor deposition (CVD). For example, amorphous silicon may be deposited using hot-wire chemical vapor deposition (CVD) (e.g., decomposing silane gas (SiH₄) using a radiofrequency discharge in a vacuum chamber) or alternatively may be sputter deposited (e.g., using ZnO/Ag). Nanocrystalline silicon may also be deposited effectively by hot-wire CVD (e.g., using a high hydrogen dilution (H₂/SiH₄=166), a high gas pressure of 2 Torr, and a high power-density of 1.0 W/cm2 at a low substrate temperature of 70° C). Similarly, protocrystalline silicon may be deposited using photo-assisted CVD (e.g., employing alternate H₂ dilution under continuous ultraviolet (UV) light irradiation).

In yet another exemplary embodiment, a cadmium telluride active layer (CdTe) is deposited over the nanostructure-film, possibly with a corresponding cadmium sulphide (CdS) layer, using close-space sublimation (CSS) (e.g., based on the reversible dissociation of the materials at high temperatures: 2CdTe(s)=Cd(g)+Te₂(g)). Alternatively, physical vapour deposition (PVD), CVD, chemical bath deposition and/or electrodeposition may be used.

In still another exemplary embodiment, copper-indium-gallium-selinide (CIGS) may be deposited over the SWNT film using a rapid thermal annealing and anodic bonding process. Such thermal annealing processes are also compatible with copper-indium-selinide (CIS) systems, the parent systems for CIGS.

In additional exemplary embodiments, gallium arsenide (GaAs) solar cells may be fabricated from epilayers grown directly on silicon substrates by atmospheric-pressure metal organic chemical vapor deposition (MOCVD); and active layers comprising quantum dots (e.g., suspended in a supporting matrix of conductive polymer or mesoporous metal oxide) may be fabricated by growing nanometer-sized semiconductor materials on various substrates (e.g., using beam epitaxy on a semi-insulating GaAs(100) substrate).

Another electrode layer may be deposited over the active layer. In the present exemplary embodiment, this electrode (e.g., cathode) needs not be transparent, and thus may comprise a conventional metal (e.g., aluminum) deposited using known techniques.

Alternatively, in other embodiments of the present invention this conventional metal electrode may be formed first, with the active layer, optional polymer, nanostructure-film and electrode grid respectively deposited thereon.

The present invention has been described above with reference to preferred features and embodiments. Those skilled in the art will recognize, however, that changes and modifications may be made in these preferred embodiments without departing from the scope of the present invention. These and various other adaptations and combinations of the embodiments disclosed are within the scope of the invention.

What is claimed is:

1. An apparatus comprising:
an electrode grid;
a functional layer; and
a network of nanostructures, wherein the electrode grid is superimposed on the network of nanostructures, and
wherein the network of nanostructures is in electrical contact with the functional layer.

2. The apparatus of claim 1, wherein the functional layer is an optoelectronic functional layer

3. The apparatus of claim 2, wherein the network of nanostructures fills gaps in the electrode grid.

4. The apparatus of claim 3, wherein the electrode grid is a metal electrode grid.

5. The apparatus of claim 4, wherein the nanostructures are nanotubes.

6. The apparatus of claim 5, further comprising a polymer, wherein the polymer is in electrical contact the network of nanostructures.

7. The apparatus of claim 6, wherein the polymer serves as a passivation layer.

8. The apparatus of claim 7, wherein the polymer forms a distinct layer adjacent to the network of nanostructures.

9. The apparatus of claim 6, wherein the polymer is a conducting polymer.

10. The apparatus of claim 9, wherein the polymer forms a composite with the network of nanostructures.

11. The apparatus of claim 1, wherein the electrode grid is at least semi-transparent.

12. The apparatus of claim 1, wherein the electrode grid comprises nanostructures.

13. The apparatus of claim 1, wherein the nanostructures comprise substantially single-wall carbon nanotubes.

14. A solar cell comprising:
a metal electrode grid;
a photosensitive functional layer; and
a network of nanostructures, wherein the electrode grid is superimposed on the network of nanostructures, and
wherein the network of nanostructures is in electrical contact with the functional layer.

15. The solar cell of claim 14, wherein the nanostructures comprise substantially carbon nanotubes.

16. The solar cell of claim 15, further comprising a polymer in electrical contact with the network of nanostructures.

17. The solar cell of claim 16, wherein the network of nanostructures has a sheet resistance of less than 300 Ω/square and an optical transmission of at least 85%.

18. A method of fabricating an optoelectronic apparatus, comprising:
depositing a network of nanostructures;
depositing a grid layer; and
patterning the grid layer into an electrode grid, wherein the electrode grid is superimposed on the network of nanostructures, and
wherein the network of nanostructures is.

19. The method of claim 18, further comprising depositing an active layer, wherein the network of nanostructures is deposited over the active layer, and
wherein the grid layer is deposited on at least one of the network of nanostructures and the functional layer.

20. The method of claim 18, wherein the grid layer is deposited on a transparent substrate, and
wherein the network of nanostructures is deposited on at least one of the transparent substrate and the grid layer.
